(19) United States
(12) Patent Application Publication
(10) Pub. No.: US 2004/0145376 A1
(43) Pub. Date: Jul. 29, 2004

(54) Network for facilitating determination of one or more characteristics of signal propagated via transmission line

(76) Inventor: Su Mi Sam, Penang (MY)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/350,890

(22) Filed: Jan. 24, 2003

(51) Int. Cl. G01R 27/04; G01R 27/32

(52) U.S. Cl. 324/642

(57) ABSTRACT

A method according to one embodiment may include transmitting, via a network, to a node comprised in the network a relatively small portion of a signal propagated via a first buried transmission line. The network may be coupled to the transmission line and may be at least partially buried. The node may be capable of being coupled to a device that is capable of determining, based at least in part upon one or more characteristics of the relatively small portion of the signal received at the node, one or more characteristics of the signal propagated via the transmission line. The relatively small portion of the signal may have a magnitude that is relatively small compared to a magnitude of the signal. Of course, many modifications and variations are possible without departing from this embodiment.

### FIELD

This disclosure relates to a network that may be used to facilitate determination of one or more characteristics of a signal that may be propagated via a transmission line.

### BACKGROUND

One conventional circuit board arrangement includes sets of electronic components mounted on layers of insulating material. The sets of electronic components and layers of insulating material are stacked on each other and laminated together. Each set of electronic components includes a plurality of electronic devices and circuit traces coupling together the electronic components. In operation of the circuit board, electrical signals may be propagated among the electronic devices via the transmission lines, such as, for example, circuit traces. Plated through-holes are formed in the circuit board to provide connectivity among the sets of electronic components.

In this conventional circuit board arrangement, one or more of the sets of electronic components is covered and/or occluded, at least in part, by a layer of insulating material. Typically, this results in the covering and/or occluding, by the layer of insulating material, of one or more circuit traces in the set of electronic components. This may limit and/or reduce the ability to probe test any such covered and/or occluded circuit traces. This may limit and/or reduce the ability to tap and examine, during, for example, testing, debugging, and/or validation of the circuit board, electrical signals propagated via any such covered and/or occluded circuit traces.

It has been proposed to include, adjacent to each such covered and/or occluded circuit trace in the circuit board, a respective circuit trace, dedicated for testing purposes, that may be coupled via a through-hole to a signal measurement device. According to this proposal, a signal propagating in a covered and/or occluded circuit trace may induce in an adjacent circuit trace dedicated for testing purposes another signal that may be transmitted to signal measurement device via the through-hole. Unfortunately, it has been found that the signal propagated to the signal measurement device may not accurately represent the signal propagated via the covered and/or occluded circuit trace, at least with respect to one or more signal characteristics (e.g., signal timing) desired to be measured by the signal measurement device, especially if the signal propagated to the signal measurement device has a relatively high frequency (e.g., a frequency greater than 1 Gigahertz (GHz)). Additionally, use of this proposed technique may reduce to undesirable degree the quality of the signal propagated via the covered and/or occluded circuit trace. This may interfere with and/or disrupt operation of circuitry in the circuit board.

### BRIEF DESCRIPTION OF THE DRAWINGS

Features and advantages of embodiments of the claimed subject matter will become apparent as the following Detailed Description proceeds, and upon reference to the Drawings, wherein like numerals depict like parts, and in which:

FIG. 1 is a diagram illustrating a system embodiment.

FIG. 2 is a flowchart illustrating operations that may be performed according to an embodiment.

Although the following Detailed Description will proceed with reference being made to illustrative embodiments, many alternatives, modifications, and variations thereof will be apparent to those skilled in the art. Accordingly, it is intended that the claimed subject matter be viewed broadly, and be defined only as set forth in the accompanying claims.

### DETAILED DESCRIPTION

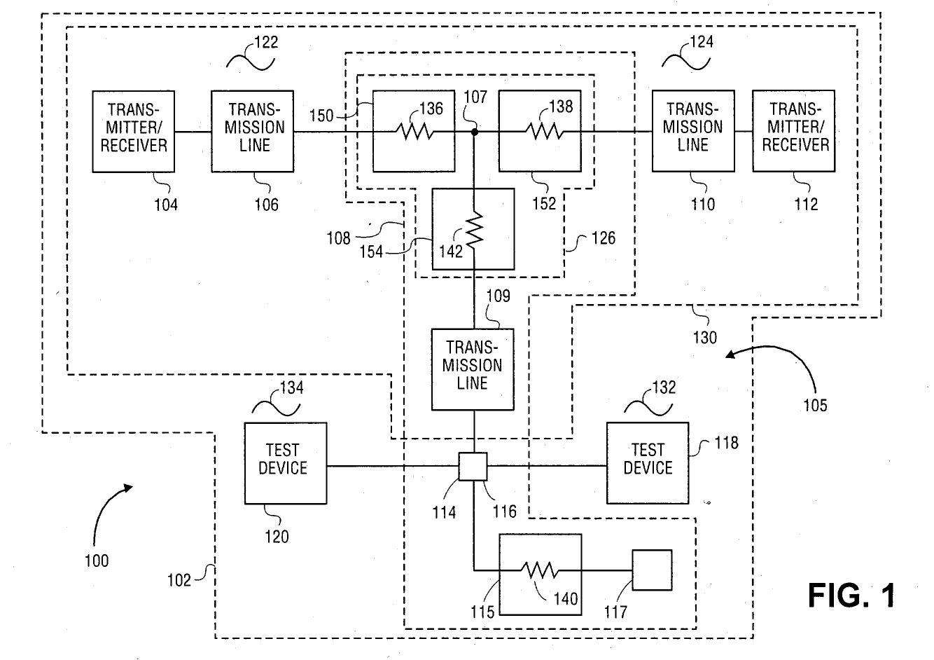

FIG. 1 illustrates a system embodiment 100 of the claimed subject matter. System 100 may include a circuit board 102, such as a system motherboard. Circuit board 102 may comprise a layers of circuitry separated by one or more layers of insulating material. The layers of circuitry and insulating material may be laminated together to form circuit board 102.

One of the layers of circuitry in circuit board 102 may comprise circuitry 105. In this embodiment, circuitry 105 may include, for example, transmitter and/or receiver circuitry 104 (hereinafter termed “transmitter circuitry 104”), transmission line 106, network 108, transmission line 110, transmitter and/or receiver circuitry 112 (hereinafter termed “receiver circuitry 112”), test device 118, and test device 120. As used herein, a “transmission line” means one or more signal conductors capable of transmitting one or more signals from one or more transmitters to one or more receivers. In this embodiment, circuitry 105 may be buried, at least in part, by insulating layer 130 (shown in ghost in FIG. 1) in circuit board 102. As used herein, a feature, component, or circuit element may be said to be “buried” if the feature or circuit element is covered and/or occluded by another feature, component, or circuit element. For example, in this embodiment, at least transmitter circuitry 104, transmission line 106, impedance network 126, transmission line 109, transmission line 110, and receiver circuitry 112 may be buried by insulating layer 130 in circuit board 102.

Although, as shown in FIG. 1, network 108 may be partially buried by insulating layer 130, alternatively, without departing from this embodiment, network 108 may be completed buried by insulating layer 130. Also, additionally or alternatively, test device 120 and/or test device 118 may be buried by insulating layer 130.

Transmitter circuitry 104 may be coupled to transmission line 106. Transmission line 106 may be coupled via network 108 to transmission line 110. Transmission line 110 may be coupled to receiver circuitry 112. In system 100, circuitry 104, circuitry 112, transmission line 106, and/or transmission line 110 may be comprised, at least in part, in e.g., one or more relatively high speed buses and/or other structures, such as, for example, processor, bus interface, memory, and clock-related circuitry. Test device 120 and/or test device 118 may be coupled to terminal 116 comprised in network 108. Test device 120 and/or test device 118 may be or comprise respective integrated circuits. As used herein, an “integrated circuit” means a semiconductor device and/or microelectronic device, such as, for example, a semiconductor integrated circuit chip.

Network 108 may comprise, for example, an impedance network 126, transmission line 109, terminal 114, termination impedance 115, and potential source 117. Impedance network 126 may comprise impedance 150 that may be coupled, via node 107, to impedances 152 and 154. Impedance 152 also may be coupled to transmission line 110. Impedance 150 also may be coupled to transmission line 106. Impedance 154 also may be coupled to transmission line 109. Impedances 150, 152, and 154 may comprise, for example, one or more respective resistors 136, 138, and 142, respectively. Additionally or alternatively, impedances 150, 152, and/or 154 may comprise one or more other respective components and/or devices (not shown), such as, for example, one or more respective transistors and/or other active devices (not shown).

Transmission line 109 may be coupled to terminal 116 that may comprise node 114. Terminal 116 also may be coupled to termination impedance 115, which impedance may be coupled to potential source 117. Potential source 117 may comprise, e.g., a common potential and/or ground potential source. Termination impedance 115 may comprise, for example, one or more resistors 140. Additionally or alternatively, impedance 115 may comprise one or more other components and/or devices (not shown), such as, for example, one or more transistors and/or other active devices (not shown).

Alternatively, although not shown in the Figures, test device 120 and/or test device 118 may not be comprised in circuit board 102, and instead, may be external to circuit board 102 and may be coupled to terminal 116 via external connections (not shown). In this alternative arrangement, terminal 116 may not be buried by insulating layer 130, but instead, may be or comprise an exposed terminal, probe pad, (e.g., comprised in a not shown connector) comprised in circuit board 102.

In this embodiment, transmitter circuitry 104 may be capable of generating and emitting a signal 122 that may be propagated via transmission line 106 to network 108. In this embodiment, the transmission line 106, network 108, and transmission line 110 may have respective impedances that may be selected so as to permit a relatively large portion 124 of signal 122 to be transmitted to receiver circuitry 112 via transmission line 110, and also to permit a relatively small portion 132 of signal 122 to be transmitted to test device 118 via network 108. That is, in this embodiment, network 108 may act as a signal splitter that may split signal 122 such a relatively small portion 132 and a remaining portion 124 of signal 122 may be generated. Signal portion 124 may be small relative to signal 122, may be large relative to signal portion 132, may be transmitted via network 108 to transmission line 110, and may be transmitted to and received by receiver circuitry 112. Signal portion 132 may be small relative to signal portion 124, and may be small relative to signal 122, may be transmitted via network 108 to node 114 comprised in terminal 116, and may be transmitted to and received by test device 118.

For example, in this embodiment, signal 122 may comprise respective voltage and/or current signals that may have respective amplitudes. Signal portion 132 and signal portion 124 each may comprise respective voltage and/or current signals that may have respective amplitudes. The respective magnitudes of the amplitudes of the respective voltage and/or current signals of signal portion 132 may be small relative to the respective magnitudes of the amplitudes of the respective voltage and/or current signals of both signal 122 and signal portion 124. The respective magnitudes of the amplitudes of the respective voltage and/or current signals of signal portion 124 may be small relative to the respective magnitudes of the amplitudes of signal 122.

In this embodiment, one or more characteristics of signal portion 132 may be indicative of one or more characteristics of signal portion 124 and/or one or more characteristics of signal 122. For example, in this embodiment, transmission line 106, network 108, and transmission line 110 may have impedances that are selected so as to permit the respective magnitudes of the amplitudes of the voltage signal and/or current signal of signal portion 132 to be a predetermined percentage of the respective magnitudes of the amplitudes of the voltage signal and/or current signal of signal 122. Additionally, in this embodiment, the impedances of transmission line 106, network 108, and transmission line 110 may be selected so to permit the respective frequencies and/or phases of the respective voltage and/or current signals in signal portion 132 and the respective frequencies and/or phases of the respective voltage and/or current signals in signal 122 to be substantially identical. Also in this embodiment, transmission line 106, network 108, and transmission line 110 may have impedances that are selected so as to permit the respective magnitudes of the amplitudes of the voltage signal and/or current signal of signal portion 124 to be a predetermined percentage of the respective magnitudes of the amplitudes of the voltage signal and/or current signal of signal 122. Additionally, in this embodiment, the impedances of transmission line 106, network 108, and transmission line 110 may be selected so to permit the respective frequencies and/or phases of the respective voltage and/or current signals in signal portion 124 and the respective frequencies and/or phases of the respective voltage and/or current signals in signal 122 to be substantially identical.

With knowledge of these impedances, the design of circuitry 105, and these predetermined percentages, it is possible to use well-known circuit analysis techniques to determine, based at least in part upon one or more characteristics (e.g., signal timing characteristics such as frequency and/or phase, the amplitudes of the voltage and/or current signals, etc.) of signal portion 132, one or more corresponding characteristics of signal 122 and/or signal portion 124. For similar reasons, one or more corresponding characteristics of signal portion 124 may be indicative of one or more corresponding characteristics of signal 122.

In system 100, test device 118 may be preprogrammed with these impedances and predetermined percentages. Test device 118 may be capable of receiving and examining signal portion 132 to determine these one or more characteristics of signal portion 132. Test device 118 may be preprogrammed with computer program instructions that, when executed by test device 118, may carry out circuit analysis algorithms that may determine, based at least in part upon these impedances, predetermined percentages, the design of circuitry 105, and these one or more characteristics of signal portion 132, one or more corresponding characteristics of signal 122 and/or signal portion 124. Test device 118 may compare these one or more characteristics of signal 122 and/or signal portion 124, as determined by test device 118, to predetermined expected values thereof, and may determine, based at least in part upon such comparison, whether circuitry 105 is operating in an expected manner. Additionally or alternatively, test device 118 may comprise logic analyzer, time domain reflectometry, and/or other types of measurement and/or analysis circuitry, that may be capable of determining based at least in part upon these one or more characteristics of signal 122 various properties of, e.g., transmission line 106 and/or transmission line 110.

In this embodiment, the operation of receiver circuitry 112 may be based, at least in part, upon signal portion 124 received by receiver circuitry 112. For example, one or more commands and/or data intended to be received by receiver circuitry 112 may be encoded as these one or more characteristics of signal 122. As stated previously, one or more such characteristics of signal portion 124 may be indicative of one or more corresponding characteristics of signal 122. Receiver circuitry 112 may be capable of determining (e.g., in a manner similar to that utilized by test device 118 to determine one or more such characteristics of signal 122 based at least in part upon one or more corresponding characteristics of signal portion 132), based at least in part upon one or more characteristics of signal portion 124, one or more corresponding characteristics of signal 122 that may encode one or more commands and/or data intended to be received by receiver circuitry 112. In response and/or based at least in part upon the one or more commands and/or data, receiver circuitry 112 may change or continue its operation (e.g., in conformity with the one or more commands and/or to utilize the data). The impedances of transmission line 106, network 108, and transmission line 110 may be selected so as to permit the signal quality and the magnitude of the voltage and/or current signals of signal portion 124 to be sufficient for receiver circuitry 112 to be able to determine, based at least in part upon these one or more characteristics of signal portion 124, the one or more commands and/or data that may be encoded by signal 122. This may permit receiver circuitry 112 to continue to operate, based at least in part, upon signal 124. Thus, advantageously, in system 100, one or more characteristics of signal 122 may be determined without substantially interfering with and/or disrupting operation of circuitry comprised in circuit board 102 such as, for example, receiver circuitry 112.

In this embodiment, the magnitude of the amplitude of the current signal of signal portion 132 may be a predetermined percentage of the magnitude of the amplitude of the current signal of signal 122. For example, in system 100, this predetermined percentage may be equal to approximately 10 percent. Thus, in system 100, the magnitude of the amplitude of the current signal of signal portion 132 may be approximately 10 percent of the magnitude of the amplitude of the current signal of signal 122. Of course, this is merely one example according to this embodiment, and many variations are possible, without departing from this embodiment.

For purposes of illustration, in this embodiment, buried impedances 150, 152, and 154 may have characteristic impedances of, e.g., 4 ohms, 4 ohms, and 605 ohms, respectively. Also for purposes of illustration, in this embodiment, buried transmission lines 106 and 110 each may have identical respective characteristic impedances of, e.g., 50 ohms each. Additionally, in order to minimize signal reflections in network 108, in this embodiment, termination impedance 115 and buried transmission line 109 each may have identical respective characteristic impedances of, e.g., 70 ohms each. Of course, these impedance values are presented for illustrated purposes, and many Variations thereof are possible without departing from this embodiment.

Alternatively, in this embodiment, if, for example, transmitter 104 and receiver 112 exhibit substantially non-zero output resistance and non-zero input resistance, respectively, of e.g., 50 ohms each, then circuitry 105 may be constructed so as to satisfy the following three equations:

$$\begin{matrix}R = \frac{( 1 - P ) * Z o}{( 3 - P )} & ( 1 ) \\ R p = \frac{1}{\frac{1}{Z o - R} - \frac{1}{Z o + R}} & ( 2 )\end{matrix}$$

R1+R2=Rp (3)

where, R is the characteristic impedance of impedance 150, Zo is the characteristic impedance of transmission line 106, R1 is the characteristic impedance of impedance 154, R2 is the characteristic impedance of transmission line 109, and P is the fraction of signal 122 that is desired to be comprised in signal 124. Thus, for example, if signal 124 and signal 122 each comprise respective voltage signals, and the magnitude of the amplitude of the voltage signal comprised in signal 124 is desired to be 90 percent of the magnitude of the amplitude of the voltage signal comprised in signal 122, then P may be equal to 0.9. In this alternative, the characteristic impedance of impedance 115 may be equal to the characteristic impedance of transmission line 109. Also in this alternative, the characteristic impedance of transmission line 106 may be equal to the characteristic impedance of transmission line 110. Additionally, in this alternative, the characteristic impedance of impedance 150 may be equal to the characteristic impedance of impedance 152. In this alternative, the values of R1 and R2 may be chosen flexibly, depending upon the particular design implementation, so long as the sum of R1 and R2 equals Rp, in accordance with equation (3). By constructing circuitry 105 in accordance with the foregoing equations and other constraints of this alternative, input impedances of transmission lines 106 and 110 may be substantially matched such that signal reflection between transmission lines 106 and 110 may be minimized. Of course, many variations are possible without departing from this embodiment.

In this embodiment, test device 120 may be or comprise a signal generator that may be capable of supplying an excitation signal 134 to transmission line 106 and/or transmission line 110 via network 108 that may permit test device 118 to determine and/or characterize, using conventional jitter and/or noise floor analysis techniques, jitter and/or noise floor characteristics of circuitry 105, based at least in part upon signal portion 132. Test device 118 may comprise circuitry that may carry out such analysis techniques, based at least in part, upon signal portion 132.

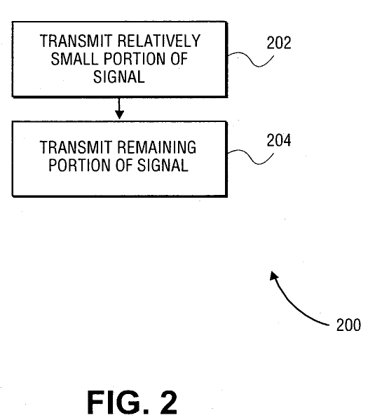

With reference being made to FIG. 2, operations 200 that may be carried out in system 100 according to one embodiment will now be described. After transmitter circuitry 104 has generated and supplied signal 122 to transmission line 106, transmission line 106 may propagate signal 122 to network 108. This may result in generation and transmission, via network 108, of relatively small portion 132 of signal 122 to node 114, and thence to test device 118, as illustrated by operation 202 in FIG. 2. Contemporaneously, this may also result in generation and transmission, via network 108 and transmission line 110, of relatively large signal portion 124 to receiver 112. Device 118 may examine one or more characteristics of signal portion 132, in the manner described previously.

Thus, in summary, one system embodiment may comprise a circuit board. The circuit board may comprise a receiver, a transmitter, a first buried transmission line via which the receiver is coupled to the transmitter, and a network to transmit to a first node comprised in the network a relatively small portion of a signal propagated from the transmitter via the first buried transmission line. The network may be coupled to the transmission line and may be at least partially buried. The node may be coupled to a device that may be capable of determining, based at least in part upon one or more characteristics of the relatively small portion of the signal received at the node, one or more corresponding characteristics of the signal propagated via the transmission line. The relatively small portion of the signal may have a magnitude that is relatively small compared to magnitude of the signal.

Advantageously, in this system embodiment, the device may be capable of determining, based at least in part upon one or more characteristics of the relatively small portion of the signal, one or more characteristics of the signal propagating in the buried transmission line in the circuit board, even if the signal propagating in the buried transmission line has a relatively high frequency (e.g., greater than 1 GHz), and without substantially interfering with and/or disrupting operation of the circuit board's circuitry. Advantageously, this may permit, for example, testing, debugging, and/or validation of the circuit board to determine, e.g., whether the transmission line and/or other components of the circuit board are operating in an expected manner.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

What is claimed is:

1. A method comprising:
transmitting, via a network, to a node comprised in the network a relatively small portion of a signal propagated via a first buried transmission line, the network being coupled to the transmission line and being at least partially buried, the node being capable of being coupled to a device that is capable of determining, based at least in part upon one or more characteristics of the relatively small portion of the signal received at the node, one or more characteristics of the signal propagated via the transmission line, the relatively small portion of the signal having a magnitude that is relatively small compared to a magnitude of the signal.

2. The method of claim 1, further comprising:
transmitting, via the network, a remaining portion of the signal to a receiver whose operation is based at least in part upon the remaining portion of the signal, the remaining portion of the signal having a magnitude that is less than the magnitude of the signal and is sufficient to enable the receiver to continue to operate based, at least in part, upon the remaining portion.

3. The method of claim 1, wherein:
a circuit board comprises the transmission line and the network.

4. The method of claim 1, wherein:
the network comprises a termination impedance coupled to the node, a second buried transmission line coupled to the node, and an impedance network coupled to the first buried transmission line.

5. The method of claim 4, wherein:
the impedance network comprises a first impedance, a second impedance, and a third impedance, the first impedance being coupled to the second buried transmission line, the second impedance, and the third impedance, the second impedance also being coupled to the first buried transmission line, the third impedance being also being coupled to a third buried transmission line that is coupled to the receiver.

6. The method of claim 1, wherein:
the node is also capable of being coupled to a signal generator capable of supplying an excitation signal to the transmission line via the network.

7. The method of claim 1, wherein:
an exposed terminal comprises the node, the exposed terminal being capable of being coupled to the device.

8. The method of claim 1, wherein:
a circuit board comprises the transmission line, the device, and the network; and
the node is a buried node.

9. The method of claim 1, wherein:
the device comprises an integrated circuit.

10. An apparatus comprising:
a network to transmit to a node comprised in the network a relatively small portion of a signal propagated via a first buried transmission line, the network being coupled to the transmission line and being at least partially buried, the node being capable of being coupled to a device that is capable of determining, based at least in part upon one or more characteristics of the relatively small portion of the signal received at the node, one or more characteristics of the signal propagated via the transmission line, the relatively small portion of the signal having a magnitude that is relatively small compared to a magnitude of the signal.

11. The apparatus of claim 10, wherein:
the network is capable of permitting a remaining portion of the signal to be transmitted via the network to a receiver whose operation is based at least in part upon the remaining portion of the signal, the remaining portion of the signal having a magnitude that is less than the magnitude of the signal and is sufficient to enable the receiver to continue to operate based, at least in part, upon the remaining portion.

12. The apparatus of claim 10, wherein:
a circuit board comprises the transmission line and the network.

13. The apparatus of claim 10, wherein:
the network comprises a termination impedance coupled to the node, a second buried transmission line coupled to the node, and an impedance network coupled to the first buried transmission line.

14. The apparatus of claim 13, wherein:
the impedance network comprises a first impedance, a second impedance, and a third impedance, the first impedance being coupled to the second buried transmission line, the second impedance, and the third impedance, the second impedance also being coupled to the first buried transmission line, the third impedance being also being coupled to a third buried transmission line that is coupled to the receiver.

15. The apparatus of claim 10, wherein:
the node is also capable of being coupled to a signal generator capable of supplying an excitation signal to the transmission line via the network.

16. The apparatus of claim 10, wherein:
an exposed terminal comprises the node, the exposed terminal being capable of being coupled to the device.

17. The apparatus of claim 10, wherein:
a circuit board comprises the transmission line, the device, and the network; and
the node is a buried node.

18. The apparatus of claim 10, wherein:
the device comprises an integrated circuit.

19. A system comprising:
a circuit board comprising:
a receiver;
a transmitter;
a first buried transmission line via which the receiver is coupled to the transmitter; and
a network to transmit to a first node comprised in the network a relatively small portion of a signal propagated from the transmitter via the first buried transmission line, the network being coupled to the transmission line and being at least partially buried, the node being coupled to a device that is capable of determining, based at least in part upon one or more characteristics of the relatively small portion of the signal received at the node, one or more characteristics of the signal propagated via the transmission line, the relatively small portion of the signal having a magnitude that is relatively small compared to a magnitude of the signal.

20. The system of claim 19, wherein:
the circuit board also comprises a second buried transmission line coupled to the first buried transmission line via the network.

21. The system of claim 20, wherein:
the first buried transmission line is coupled to the receiver and to the network;
the second buried transmission line is coupled to the transmitter and to the network.

22. The system of claim 21, wherein:
the network comprises a termination impedance and a third buried transmission line;
the node is coupled to the termination impedance and to the third buried transmission line; and
the termination impedance and the third buried transmission line have respective characteristic impedances that are identical.

23. The system of claim 22, wherein:
the first transmission line and the second transmission line have respective characteristic impedances that are identical.

24. The system of claim 23, wherein:
the characteristic impedance of the first transmission line is different from the characteristic impedance of the third transmission line.

25. The system of claim 21, wherein:
the network comprises an impedance network via which the first transmission line is coupled to the second transmission line.

26. The system of claim 25, wherein:
the impedance network comprises a first impedance, a second impedance, and a third impedance; and
the first impedance is coupled, via a second node, to the second impedance and to the third impedance.

27. The system of claim 26, wherein:
the first impedance, the second impedance, and the third impedance have respective characteristic impedances, the characteristic impedance of the first impedance being identical to the characteristic impedance of the second impedance, the characteristic impedance of the third impedance being different from the characteristic impedance of the first impedance.

28. The system of claim 27, wherein:
the first node is coupled to the impedance network via a third buried transmission line; and
the first node is also coupled to a termination impedance.
